(19) United States
(12) Patent Application Publication
(10) Pub. No.: US 2026/0196982 A1
(43) Pub. Date: Jul. 9, 2026

(54) COMPOSITE FILTER AND COMMUNICATION DEVICE

(71) Applicant: KYOCERA CORPORATION, Kyoto-shi, Kyoto (JP)

(72) Inventors: Tsuyoshi NAKAI, Soraku-gun, Kyoto (JP); Junichiro TAKIKAWA, Nara-shi, Nara (JP); Toshiya KIMURA, Soraku-gun, Kyoto (JP)

(73) Assignee: KYOCERA CORPORATION, Kyoto-shi, Kyoto (JP)

(21) Appl. No.: 19/128,309

(22) PCT Filed: Nov. 7, 2023
(86) PCT No.: PCT/JP2023/040029

§ 371 Date: May 8, 2025

(30) Foreign Application Priority Data
Nov. 11, 2022 (JP) 2022-180916

(51) Int. Cl. H03H 9/56

(52) U.S. Cl. CPC H03H 9/568

(57) ABSTRACT

In a composite filter, a first hybrid includes first to fourth ports. A first filter is connected to the second port of the first hybrid and has a first passband. A second filter is connected to the third port and has a second passband that is not overlapped with the first passband. A third filter is connected to the fourth port and has the second passband. A resonator is branched from a signal path from the first filter to the second port to be connected to a reference potential portion and has a resonant frequency within the second passband. In addition to the above components or alternatively, a fourth filter is branched from a signal path from the first filter to the second port to be connected to a reference potential portion and transmits a signal having a frequency within the second passband to the reference potential portion.

### TECHNICAL FIELD

The present disclosure relates to a composite filter including two or more filters and a communication apparatus including the composite filter.

### BACKGROUND OF INVENTION

A known composite filter includes two or more filters and a 90° hybrid coupler (the 90° hybrid coupler may be hereinafter simply referred to as a “hybrid”) connected to the two or more filters (for example, Patent Literatures 1 and 2). The composite filter disclosed in Patent Literatures 1 and 2 is composed as a duplexer. In this duplexer, an antenna, a first filter, a second filter, and a third filter are connected to the respective four ports of the hybrid. The first filter is used as, for example, a transmission filter. The second filter and the third filter are used as, for example, reception filters having the same passband.

### CITATION LIST

### Patent Literature

Patent Literature 1: International Publication No. 2009/078095

### SUMMARY

In an aspect of the present disclosure, a composite filter includes a first hybrid, a first filter, a second filter, a third filter, and a resonator. The first hybrid is composed of a 90° hybrid coupler including a first port, a second port, and a third port and a fourth port to which a signal input into the first port or the second port is distributed. The first filter is connected to the second port and has a first passband. The second filter is connected to the third port and has a second passband that is not overlapped with the first passband. The third filter is connected to the fourth port and has the second passband. The resonator is branched from a signal path from the first filter to the second port to be connected to a reference potential portion and has a resonant frequency within the second passband.

In an aspect of the present disclosure, a composite filter includes a first hybrid, a first filter, a second filter, a third filter, and a fourth filter. The first hybrid is composed of a 90° hybrid coupler including a first port, a second port, and a third port and a fourth port to which a signal input into the first port or the second port is distributed. The first filter is connected to the second port and has a first passband. The second filter is connected to the third port and has a second passband that is not overlapped with the first passband. The third filter is connected to the fourth port and has the second passband. The fourth filter is branched from a signal path from the first filter to the second port to be connected to a reference potential portion and transmits a signal having a frequency within the second passband to the reference potential portion.

In an aspect of the present disclosure, a communication apparatus includes any of the composite filter described above, an antenna, and an integrated circuit element. The antenna is connected to the first port. The integrated circuit element is electrically connected to an opposite side of the first hybrid with respect to the first filter and each of the second filter and the third filter.

### BRIEF DESCRIPTION OF THE DRAWINGS

FIG. 1 is a schematic diagram illustrating the configuration of a composite filter in first and second embodiments.

FIG. 2 is a schematic diagram illustrating the configuration of part of the composite filter in the first embodiment.

FIG. 3 is a schematic diagram illustrating an example of the configuration of a resonator in the composite filter in the first embodiment.

FIG. 4 is a schematic diagram illustrating an example of characteristics of the resonator in the composite filter in the first embodiment.

FIG. 5 is a graph indicating nonlinear distortion in an example of the first embodiment.

FIG. 6 is a schematic diagram illustrating the configuration of part of the composite filter in the second embodiment.

FIG. 7A is a graph indicating transmission characteristics in an example of the second embodiment.

FIG. 7B is a graph indicating isolation characteristics in the example of the second embodiment.

FIG. 8A is a graph indicating the nonlinear distortion flowing into a reception terminal in the example of the second embodiment.

FIG. 8B is a graph indicating the nonlinear distortion flowing into a reference potential portion in the example of the second embodiment.

FIG. 9 is a schematic diagram illustrating the configuration of a composite filter in a third embodiment.

FIG. 10 is a plan view schematically illustrating an example of the configuration of a resonator in the composite filter in the embodiment.

FIG. 11 is a block diagram illustrating an example of the configuration of a communication apparatus including the composite filter in the embodiment.

### DESCRIPTION OF EMBODIMENTS

Embodiments according to the present disclosure will be described with reference to the drawings. The drawings used in the following description are schematically illustrated. Accordingly, for example, the ratios of sizes and the likes on the drawings do not necessarily coincide with the actual ratios of sizes and the likes. Different ratios of sizes and the likes may be used in different drawings. Specific shapes, sizes, and/or the likes may be exaggerated or details of the specific shapes, sizes, and/or the likes may be omitted. However, the above description does not deny the actual shapes and/or sizes that coincide with the shapes and/or sizes on the drawings and/or extraction of features of the shapes and/or sizes from the drawings.

In the description of multiple aspects, only the difference between aspects that are subsequently described and aspects that are previously described is basically mentioned for the aspects that are subsequently described. Matters that are not specifically mentioned may be considered to be the same as and/or similar to the aspects that are previously described or may be estimated from the aspects that are previously described. The same reference numerals and letters may be added to the corresponding components in the multiple aspects for convenience even if differences lie. Conversely, different reference numerals and letters may be added to the same components for convenience of description. In the subsequent description of the multiple aspects, only the reference numerals and letters of the aspects that are previously described may be used for convenience. However, the reference numerals and letters of the aspects that are previously described may be replaced with the reference numerals and letters of the aspects that are subsequently described unless inconsistency or the like is found.

In the present disclosure, when the phase of a signal is described to be, for example, “shifted”, the phase may be advanced or may be delayed. However, in the above representation, for example, “shifted” means only one of “advanced” and “delayed” commonly in various components, various signals, and so on for convenience unless inconsistency or the like is found. For example, when the phase of a second signal is described to be shifted from the phase of a first signal by 90° and the phase of a fourth signal is described to be shifted from the phase of a third signal by 90°, both the former shift and the latter shift mean the phase advance of 90° or the phase delay of 90°.

In the present disclosure, representation of “being electrically connected to an opposite side” is used. The “opposite side” means, for example, the “output side” with respect to the input side or the “input side” with respect to the output side.

### Summary of Embodiment

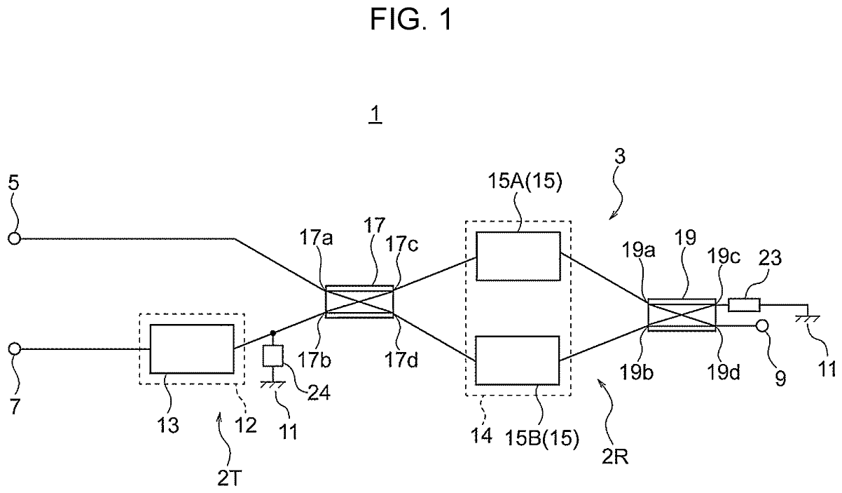

FIG. 1 is a circuit diagram illustrating the configuration of a composite filter 1 in an embodiment.

The composite filter 1 is composed as a duplexer. The composite filter 1 includes, for example, a transmission path 2T that filters a transmission signal from a transmission terminal 7 (a first terminal) and outputs the transmission signal to an antenna terminal 5 (a common terminal) and a reception path 2R that filters a reception signal from the antenna terminal 5 and outputs the reception signal to a reception terminal 9 (a second terminal).

A transmission filter system 12 that directly performs the filtering of the transmission signal is provided on the transmission path 2T. The transmission filter system 12 includes a transmission filter 13. A reception filter system 14 that directly performs the filtering of the reception signal is provided on the reception path 2R. The reception filter system 14 includes reception filters 15A and 15B (the reception filters 15A and 15B may be referred to as a reception filter 15 without distinction).

The transmission filter system 12 (the transmission filter 13) transmits a signal in a transmission band (attenuates a signal outside the transmission band). The reception filter system 14 (the reception filter 15) transmits a signal in a reception band (attenuates a signal outside the reception band). The transmission band and the reception band are frequency bands that are different from each other (the transmission band is not overlapped with the reception band). In other words, the transmission filter 13 and the reception filter 15 have passbands that are not overlapped with each other. In the composite filter 1, a portion that includes the transmission filter 13 and the reception filter 15 and that directly contributes to the filtering (a portion excluding hybrids described below) is a portion corresponding to a common branching filter (a branching filter main body 3).

A first hybrid 17 composed of a 90° hybrid coupler intervenes between the antenna terminal 5 and the transmission filter 13, and the reception filters 15A and 15B. The first hybrid 17, for example, contributes to reduction in nonlinear distortion (a distortion signal), as described below.

The first hybrid 17 includes four ports 17a to 17d. The ports 17a to 17d have relationship in which a signal input into the port 17a or 17b is distributed to the ports 17c and 17d when the relationship is described simply based on the technical common knowledge. The antenna terminal 5 and the transmission filter 13 are connected to the ports 17a and 17b, respectively, and the reception filters 15A and 15B are connected to the ports 17c and 17d, respectively.

Upon input of the transmission signal into the transmission terminal 7 from the outside of the composite filter 1, the transmission signal is filtered by the transmission filter 13 and is input into the first hybrid 17. The transmission signal input into the first hybrid 17 is divided into two transmission signals the phases of which are shifted from each other by 90° to be distributed to the two reception filters 15. Since the transmission band is not overlapped with the reception band, the two transmission signals resulting from the division are reflected from the two reception filters 15 and are input into the first hybrid 17 again. The two transmission signals that are input are combined in phase by the first hybrid 17 and are output to the antenna terminal 5.

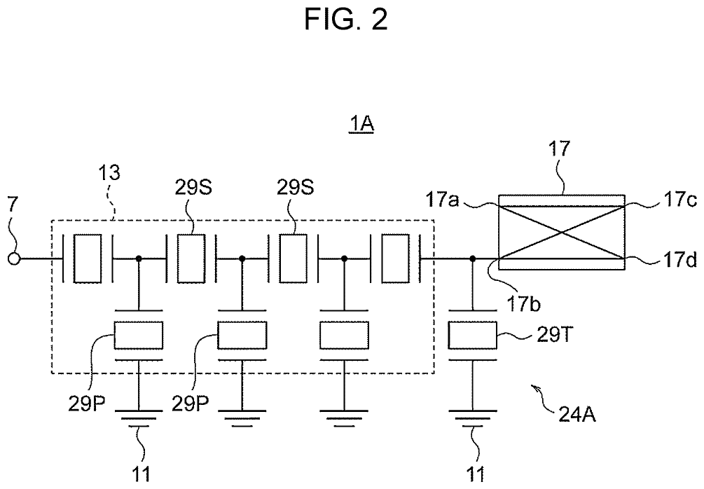

The composite filter 1 includes a trap 24 that is branched from a signal path from the transmission filter 13 to the port 17b to be connected to a reference potential portion 11. The trap 24 is capable of transmitting a signal having a frequency within the reception band to the reference potential portion 11. For example, the trap 24 includes a trap resonator 29T (FIG. 2) having a resonant frequency in the reception band.

Accordingly, the nonlinear distortion (for example, PIM3: a third-order passive intermodulation distortion) that occurs in the transmission filter 13 and that has a frequency within the reception band is let out to the reference potential portion 11 via the trap 24. As a result, the probability that the nonlinear distortion is transmitted through the reception filter 15 and flows into the reception terminal 9 is reduced.

In a common duplexer that does not include the first hybrid 17, both the transmission filter 13 and the reception filter 15 are directly connected to the antenna terminal 5. Accordingly, if the trap 24 is connected to the output side (the antenna terminal 5 side) of the transmission filter 13 as in the composite filter 1, the signal to be to flow from the antenna terminal 5 to the reception filter 15 also flows into the trap 24. Accordingly, the trap 24 is not supposed from the common duplexer.

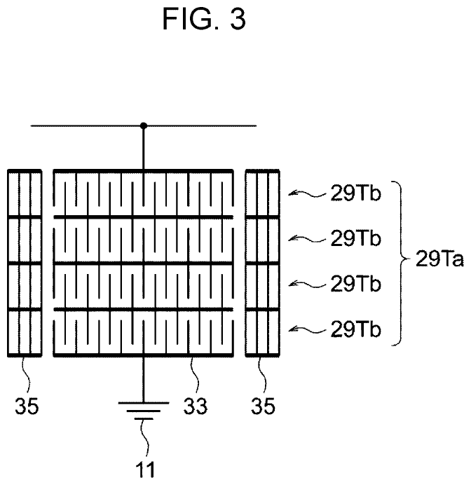

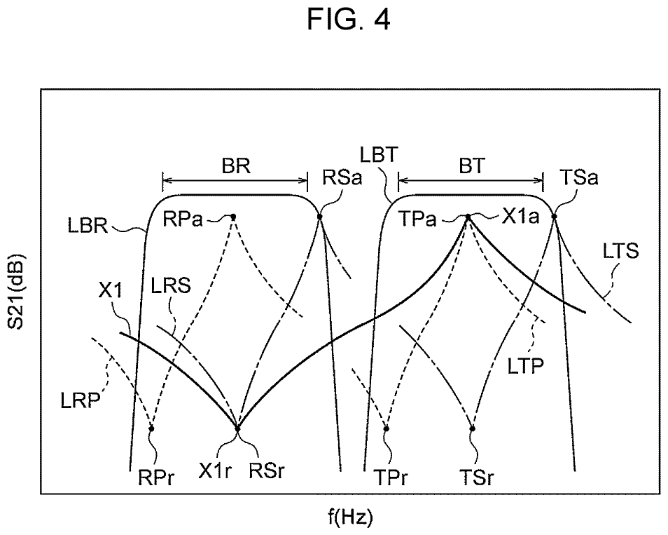

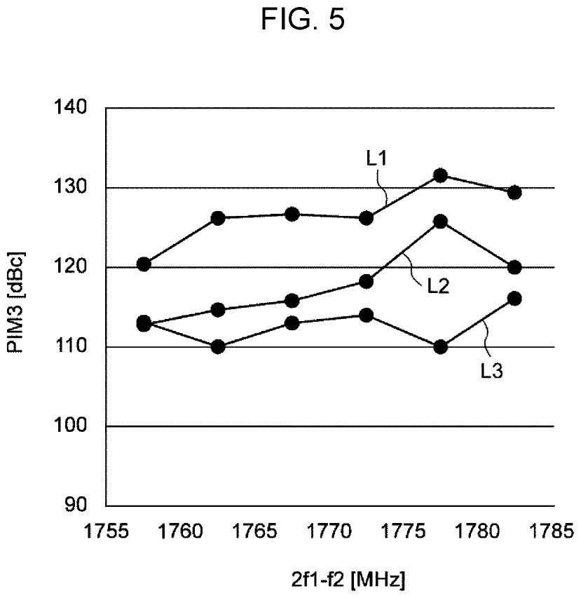

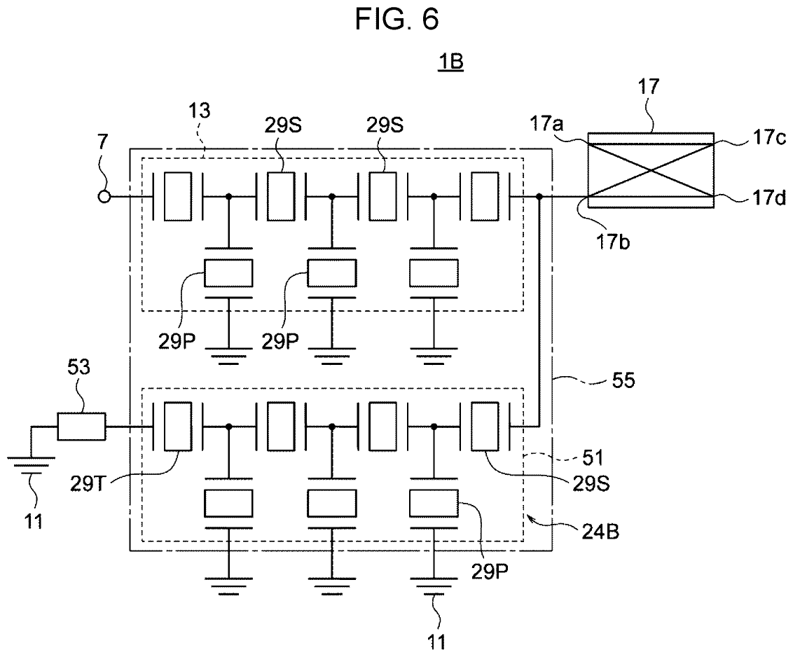

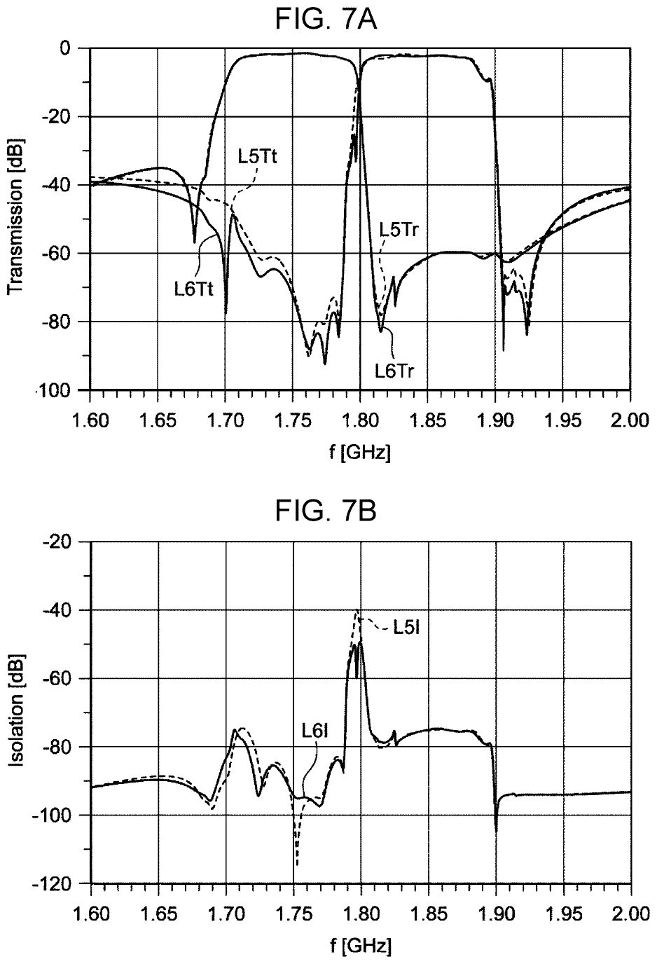

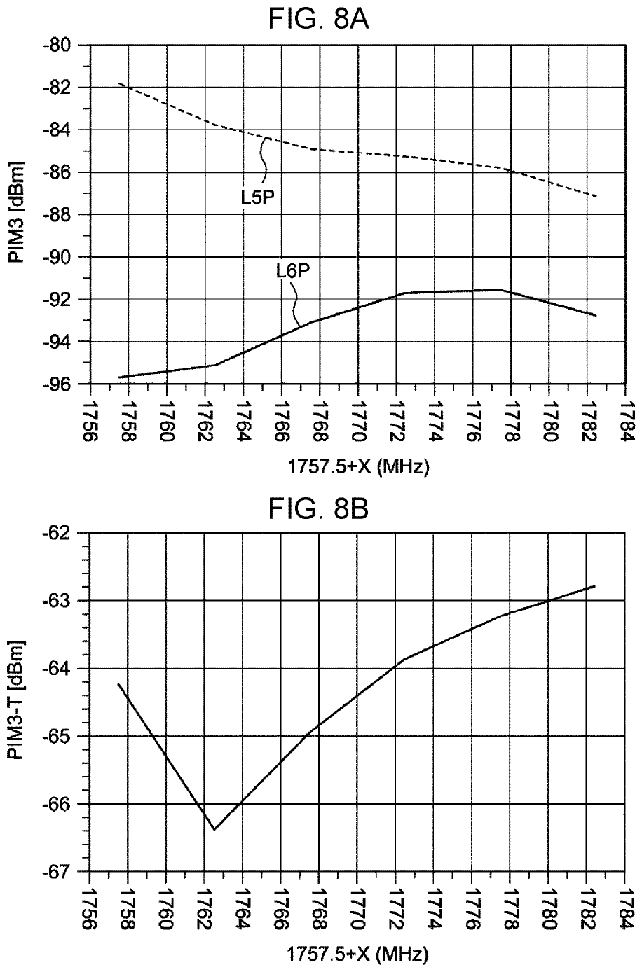

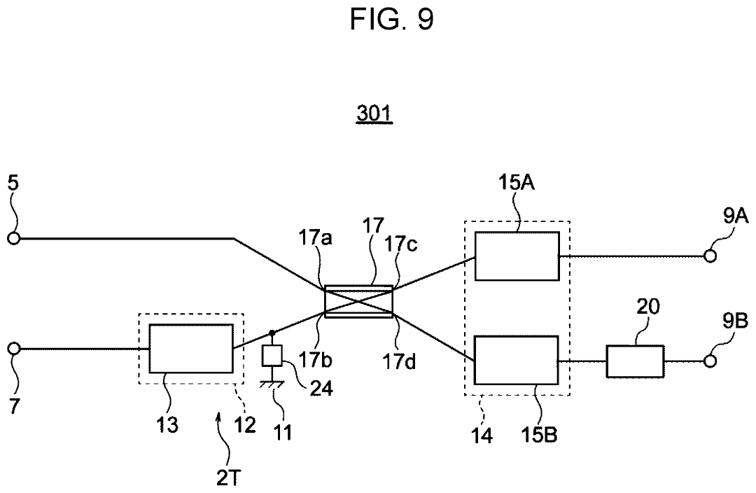

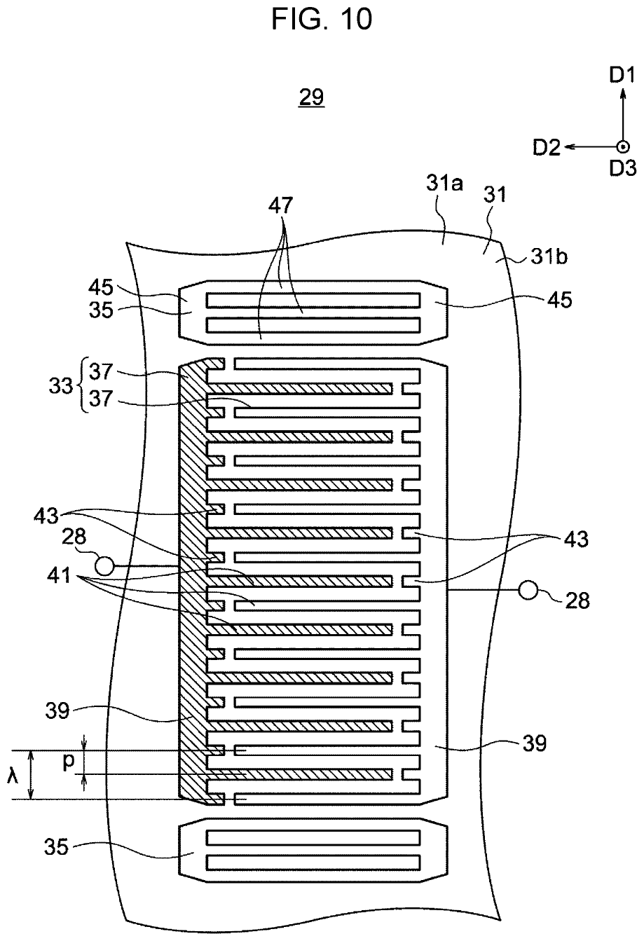

The summary of the embodiment is described above. The embodiment described above differs from a first embodiment and a second embodiment, which will be described below, in the specific configuration of the trap 24. A third embodiment is common to the first embodiment and the second embodiment in a point in which the probability that the nonlinear distortion occurring in the transmission filter 13 is transmitted through the reception filter 15 is reduced with the trap 24, although the entire configuration of the third embodiment is different from the entire configurations of the first embodiment and the second embodiment. Various embodiments according to the present disclosure will be roughly described below in the following order.
1. First Embodiment
   1.1. Configuration of composite filter (excluding configuration of trap) (FIG. 1)
      1.1.1. Filter
      1.1.2. Hybrid
      1.1.3. Termination resistor
      1.1.4. Others
   1.2. Operation of composite filter (excluding operation of trap)
      1.2.1. Transmission of transmission signal
      1.2.2. Transmission of reception signal
      1.2.3. Example of reduction in nonlinear distortion
   1.3. Trap
      1.3.1. Configuration of trap (FIG. 2)
      1.3.2. Example of configuration of resonator in trap (FIG. 3)
      1.3.3. Example of characteristics of resonator in trap (FIG. 4)
   1.4. Characteristics of comparative example and example (FIG. 5)
2. Second Embodiment
   2.1. Trap (FIG. 6)
   2.2. Characteristics of comparative example and example (FIG. 7A to FIG. 8B)
3. Third embodiment (FIG. 9)
4. Example of acoustic wave resonator (FIG. 10)
5. Example of communication apparatus including composite filter (FIG. 9)
6. Summarization of embodiments

### 1. First Embodiment

The composite filter 1 in the first embodiment will be described. The composite filter 1 in the first embodiment may be referred as a composite filter 1A (a reference numeral and letter is illustrated in FIG. 2).

### (1.1. Configuration of Composite Filter (Excluding Configuration of Trap)

FIG. 1 described above illustrates the configuration of the composite filter 1 in the first and second embodiments. The summary of the composite filter 1 is described above. The composite filter 1 includes a second hybrid 19, in addition to the components described above. The second hybrid 19 intervenes between the reception terminal 9 and the reception filters 15A and 15B. The composite filter 1 includes a termination resistor 23 connected to a port 19c of the second hybrid 19, which is not used. The composite filter 1 may include a matching circuit at an appropriate position although not particularly illustrated. The components in the composite filter 1 will be sequentially described below.

### (1.1.1. Filter)

The transmission filter 13 is a band pass filter having a certain transmission band as the passband. Similarly, the reception filter 15 is a band pass filter having a certain reception band as the passband. The transmission band and the reception band may conform to, for example, various standards. The transmission band may include two or more transmission bands conforming to a certain standard. The same applies to the reception band.

The reception filters 15A and 15B support the same reception band. In other words, the passband of the reception filter 15A is the same as the passband of the reception filter 15B substantially and/or in design. For example, the configuration of the reception filter 15A is the same as or similar to the configuration of the reception filter 15B, and the reception filters 15A and 15B have the same characteristics substantially and/or in design. However, the reception filters 15A and 15B may be fine-tuned so that the passbands of the reception filters 15A and 15B are slightly different from each other and/or the characteristics of the reception filters 15A and 15B are slightly different from each other.

The transmission filter 13 and the reception filter 15 may have various specific configurations and, for example, the transmission filter 13 and the reception filter 15 may have known configurations or configurations to which known configurations are applied. For example, the transmission filter 13 and/or the reception filter 15 may a piezoelectric filter including a piezoelectric body, may be a dielectric filter using electromagnetic waves in a dielectric body, may be an LC filter in which an inductor is combined with a capacitor, or may be a combination of two or more of the above ones. The piezoelectric filter may be, for example, an acoustic wave filter using acoustic waves or may be a filter other than the acoustic wave filter (for example, a filter using a piezoelectric vibrator).

The acoustic wave filter may have any specific configuration. For example, the acoustic wave filter may be a ladder filter in which acoustic wave resonators described below (FIG. 10) are connected in a ladder shape or may be a multi-mode filter (including a double-mode filter) in which IDT (interdigital transducer) electrodes 33 described below (FIG. 10) are aligned in a propagation direction of the acoustic waves. The acoustic waves may be, for example, SAWs (surface acoustic waves), BAWs (bulk acoustic waves), boundary acoustic waves, or plate waves (however, theses waves are not necessarily discriminated). The BAWs may propagate in a direction in which a piezoelectric layer (refer to description of a piezoelectric substrate 31 described below) expands or may propagate in the thickness direction of the piezoelectric layer. In the description of the embodiment, an aspect may be exemplified with no description, in which the transmission filter 13 and the reception filter 15 are composed of the acoustic wave filters.

### (1.1.2. Hybrid)

The first hybrid 17 includes the four ports 17a to 17d used for input and/or output of signals and has functions as a distributor, a combiner, and a 90° phase shifter. The first hybrid 17 may have a known configuration or a configuration to which a known configuration is applied. For example, the first hybrid 17 may be of a distributed constant or of a lumped constant although not particularly illustrated. A branch line coupler is known as the first hybrid 17.

The respective ports 17a and 17b on the left side of FIG. 1 are electrically connected to the respective ports 17c and 17d on the right side of FIG. 1. The electrical connection here means that a signal is capable of being transmitted between the ports. Accordingly, for example, the signal input into the port 17a is capable of being output from the ports 17c and 17d.

Description based on the positional relationship between the ports 17a to 17d on a graphic representing the first hybrid 17 may be provided in the present embodiment for convenience. However, the positional relationship between the four ports 17a to 17d on the graphic may not coincide with the actual positional relationship between the four ports 17a to 17d.

The signal input into the port 17a on the left side of FIG. 1 is distributed to the ports 17c and 17d on the right side of FIG. 1. The distribution ratio (the ratio in strength between the two distributed signals) at this time is 1:1. The strength is, for example, voltage, current, and/or electric power. The phases of the two distributed signals are shifted from each other by 90°.

The phase of the signal before distribution (for example, the signal input into the port 17a) may coincide with the phase of one of the two signals after distribution (for example, the signal output from the port 17c). Alternatively, the phase of the signal before distribution may be different from the phases of both of the two signals after distribution. However, the phase of the signal before distribution may be described to coincide with the phase of one of the two signals after distribution in the present embodiment for convenience. Specifically, the phases of the signals at the ports at the same position in the up-down direction of FIG. 1 (for example, the ports 17a and 17c) may be described to coincide with each other.

Although the case in which the signal is input into the port 17a is exemplified, the above operation is applied to a case in which the signal is input into another port, among the ports 17b to 17d. Specifically, the signal input into one of the two ports positioned at one side in the left-right direction of FIG. 1 is distributed in the distribution ratio of 1:1 to be output from the two ports positioned at the other side in the left-right direction of FIG. 1. At this time, the phases of the two distributed signals are shifted from each other by 90°.

As described above, the shift of the phase means only one of the advance and the delay commonly in various components, various signals, and so on for convenience. In representation on the drawing, the phase of the signal output from the port (for example, 17c) at the same position in the up-down direction of FIG. 1 as that of the port (for example, 17a) into which the signal is input is shifted from the phase of the signal output from the port (for example, 17d) at a different position in the up-down direction of FIG. 1 from that of the port into which the signal is input by 90°.

Since the hybrid operating in the above manner is called the 90° hybrid, the relationship between the four ports of the first hybrid 17 is capable of being identified from only description of part of the ports. For example, the port 17d is described to be the port to which the signal the phase of which is shifted from the phase of the signal distributed from the port 17a to the port 17c by 90° is distributed from the port 17a. This description leads the fact that the port 17a and the remaining port 17b are positioned at the same side in the left-right direction of FIG. 1 and the port 17c and the port 17d are positioned at the opposite side and the fact that the port 17a and the port 17c are positioned at the same side in the up-down direction of FIG. 1 and the port 17b and the port 17d are positioned at the opposite side. When the relationship between the four ports is described based on the signal distributed from the port 17a in the above manner, the first hybrid 17 may not be provided in an aspect in which an intended signal is actually input from the port 17a. The same applies to cases in which the relationship between the four ports is described using distribution from the other ports.

For example, when the two ports (for example, the ports 17c and 17d) positioned at the same side in the left-right direction of FIG. 1 may not be particularly discriminated, the relationship between the four ports is capable of being described more simply. For example, the ports 17c and 17d are described to be the ports to which the signal input into the port 17a or 17b is distributed, as described above in the description of the summary of the embodiment. This description leads the fact that the port 17a and the remaining port 17b are positioned at the same side in the left-right direction of FIG. 1 and the port 17c and the port 17d are positioned at the opposite side. When the relationship between the four ports is described based on the signal distributed from the port 17a or 17b in the above manner, the first hybrid 17 may not be provided in an aspect in which an intended signal is actually input from the port 17a or 17b. The same applies to cases in which the relationship between the four ports is described using distribution from the other ports.

Upon input of the signal into each of the ports 17a and 17b on the left side of FIG. 1, each signal is distributed in the manner described above and the distributed signals are combined. For example, the signal input into the port 17a is called a first signal and the signal input into the port 17b is called a second signal. The signals resulting from distribution of the first signal into the ports 17c and 17d are called a third signal and a fourth signal, respectively. The phase of the fourth signal is shifted from the phase of the third signal by 90°. The signals resulting from distribution of the second signal into the ports 17c and 17d are called a fifth signal and a sixth signal, respectively. The phase of the fifth signal is shifted from the phase of the sixth signal by 90°. The signal resulting from combination of the third signal and the fifth signal is output to the port 17c and the signal resulting from combination of the fourth signal and the sixth signal is output to the port 17d. Although the case is exemplified, in which the signals are input into the two ports 17a and 17b on the left side of FIG. 1, the same applies to a case in which the signals are input into the two ports 17c and 17d on the right side of FIG. 1.

As described above, for example, a phase difference may be made between the first signal (input into the port 17a) and the third signal (distributed to the port 17c with no phase shift), and a phase difference may be made between the second signal (input into the port 17b) and the sixth signal (distributed to the port 17d with no phase shift). At this time, the two phase differences are equal to each other. The two phase differences when the signals are transmitted in the opposite direction are equal to the above two phase differences.

Although the first hybrid 17 is described above, the above description may be incorporated in the second hybrid 19. In this case, the word of the first hybrid 17 is replaced with the word of the second hybrid 19 and the words of the ports 17a to 17d are replaced with the words of ports 19a to 19d. The specific configuration of the first hybrid 17 (for example, the shape, the size, and so on of a conductor) may be the same as or different from the specific configuration of the second hybrid 19.

In the first hybrid 17, the connection relationship between the ports 17a to 17d and other elements (the antenna terminal 5, the transmission filter 13, and the two reception filters 15) is described above. In the second hybrid 19, the port 19a is connected to the reception filter 15A, the port 19b is connected to the reception filter 15B, the port 19c is connected to the termination resistor 23, as described above, and the port 19d is connected to the reception terminal 9.

### (1.1.3. Termination Resistor)

The termination resistor 23 has, for example, a predetermined resistance value and the port 19c of the second hybrid 19 is connected to the reference potential portion 11 via the termination resistor 23. This reduces, for example, the reflection of the signal flowing from the port 19a and/or 19b to the port 19c. Although the resistance value of the termination resistor 23 may be appropriately set in accordance with impedance at the second hybrid 19 side with respect to the termination resistor 23, the resistance value of the termination resistor 23 is generally 50Ω.

The termination resistor 23 may have various configurations and, for example, the termination resistor 23 may have a known configuration or a configuration to which a known configuration is applied. For example, the termination resistor 23 may be a mounted resistor, an embedded resistor, or a built-in resistor positioned in and/or on a circuit board (for example, a multilayer substrate) (not illustrated) of the composite filter 1 although not particularly illustrated. The termination resistor 23 may be a built-in resistor (for example, a conductor pattern overlapped with a top face 31a of a piezoelectric body 31b described below) positioned in the piezoelectric substrate 31 described below. The termination resistor 23 may be provided outside the composite filter 1, unlike the example in the drawing.

### (1.1.4. Others)

The composite filter 1 may have any entire configuration from the structural viewpoint. For example, the composite filter 1 may be configured as one chip mounted on the circuit board. The composite filter 1 may be configured as part of a module including the circuit board and multiple chips mounted on the circuit board.

For example, one chip or part of the module, which serves as the composite filter 1, may be configured by mounting one or multiple chips composing the first hybrid 17, the second hybrid 19, the transmission filter 13, and the reception filter 15 on the circuit board. In this aspect, two or more of the transmission filter 13 and the reception filters 15A and 15B may be assembled as one chip or part of the transmission filter 13 and part of the reception filters 15A and 15B may be assembled as one chip.

For example, one chip or part of the module, which serves as the composite filter 1, may be configured by mounting the chip including the transmission filter 13 and the reception filter 15 on the circuit board (for example, the multilayer substrate) and incorporating the first hybrid 17 and the second hybrid 19 in the circuit board. The incorporation may be embedding of the chip or built-in of the hybrid in the circuit board with the conductor in the circuit board.

The antenna terminal 5, the transmission terminal 7, the reception terminal 9, and the reference potential portion 11 may be included in the composite filter 1 or may be provided outside the composite filter 1. For example, the various terminals may not be provided, as in an aspect in which an antenna built in the multilayer substrate is directly connected to the first hybrid 17 built in the multilayer substrate via no terminal and the antenna terminal 5 is not provided.

The reference potential portion 11 is a portion (conductor) to which reference potential is applied. More specifically, for example, the reference potential portion 11 may be a terminal to which the reference potential is applied or may be a component (for example, a shield) other than the terminal. Although 0 V is typically exemplified as the reference potential, the reference potential is not limited to this.

The reference potential portion 11 may be illustrated in multiple positions in the drawings. The reference potential portion 11 illustrated in multiple positions may be actually different portions or may be considered to be separately illustrated for convenience of illustration. The two or more reference potential portions 11 serving as different portions may be connected to each other or may not be connected to each other in the composite filter 1.

### (1.2. Operation of Composite Filter (Excluding Operation of Trap)

An operation (action) of the composite filter will be described. However, an action of the trap 24 is not mentioned here.

### (1.2.1. Transmission of Transmission Signal)

The summary of the action to transmit the signal (the transmission signal) input from the outside of the composite filter 1 into the transmission terminal 7 to the antenna terminal 5 is described above. More specifically, the action is taken in the following manner.

The signal that is filtered by the transmission filter 13 and that has a frequency within the passband of the transmission filter 13 is input into the port 17b of the first hybrid 17. The signal input into the port 17b is distributed to the ports 17c and 17d. The phase of the signal distributed to the port 17c is shifted from the phase of the signal distributed to the port 17d by 90°.

Since the signal that is distributed to the port 17c and that is output from the port 17c is a signal having a frequency within the passband (the transmission band) of the transmission filter 13, the signal is not transmitted through the reception filter 15A having the passband (the reception band) different from the transmission band and is reflected by the reception filter 15A. Accordingly, the signal output from the port 17c is returned to the port 17c. Similarly, the signal that is distributed to the port 17d and that is output from the port 17d is reflected by the reception filter 15B and is returned to the port 17d.

The signal that has been returned to the port 17c is distributed to the ports 17a and 17b. At this time, the phase of the signal distributed to the port 17b is shifted from the phase of the signal distributed to the port 17a by 90°. Similarly, the signal that has been returned to the port 17d is distributed to the ports 17a and 17b. At this time, the phase of the signal distributed to the port 17a is shifted from the phase of the signal distributed to the port 17b by 90°.

The signal that is transmitted from the transmission filter 13 sequentially via the ports 17b and 17c, that is reflected by the reception filter 15A, that is returned to the port 17c, and that is transmitted to the port 17a is in phase with the signal that is transmitted from the transmission filter 13 sequentially via the ports 17b and 17d, that is reflected by the reception filter 15B, that is returned to the port 17d, and that is transmitted to the port 17a because both of the signals are subjected to the shift in phase by 90° once. Accordingly, the two signals are combined to be output from the port 17a to the antenna terminal 5.

In contrast, the signal that is transmitted from the transmission filter 13 sequentially via the ports 17b and 17d, that is reflected by the reception filter 15B, that is returned to the port 17d, and that is transmitted to the port 17b is not subjected to the shift in phase by 90°. The signal that is transmitted from the transmission filter 13 sequentially via the ports 17b and 17c, that is reflected by the reception filter 15A, that is returned to the port 17c, and that is transmitted to the port 17b is subjected to the shift in phase by 90° twice. Accordingly, since the two signals are in opposite phase and are cancelled out, the signal is not output from the port 17b.

Although the signal that is returned to the port 17c or 17d is described to be distributed to the port 17b for convenience of description, the output of no signal from the port 17b substantially means that no signal is distributed to the port 17b. In other words, the strength of the signal to be output to the antenna terminal 5 is equal to the strength of the signal input into the transmission terminal 7 if insertion loss is ignored.

When only the first hybrid 17 is focused on, the port 17b to which the transmission filter 13 is connected is not electrically connected to the port 17a to which the antenna terminal 5 is connected. The signal from the transmission filter 13 is transmitted to the antenna terminal 5 using the reflection by the reception filter 15, as described above. Also in such an aspect, the transmission filter 13 may be represented as being connected to the antenna terminal 5 via the first hybrid 17 for convenience.

### (1.2.2. Transmission of Reception Signal)

The signal (the reception signal) input from the antenna terminal 5 to the port 17a of the first hybrid 17 is distributed to the ports 17c and 17d. The phase of the signal distributed to the port 17d is shifted from the phase of the signal distributed to the port 17c by 90°.

The signal that is distributed to the port 17c and that is output from the port 17c is input into the port 19a of the second hybrid 19 via the reception filter 15A. The signal that is distributed to the port 17d and that is output from the port 17d is input into the port 19b of the second hybrid 19 via the reception filter 15B.

The signal input into the port 19a is distributed to the ports 19c and 19d. At this time, the phase of the signal distributed to the port 19d is shifted from the phase of the signal distributed to the port 19c by 90°. Similarly, the signal input into the port 19b is distributed to the ports 19c and 19d. At this time, the phase of the signal distributed to the port 19c is shifted from the phase of the signal distributed to the port 19d by 90°.

The signal that is transmitted from the antenna terminal 5 to the port 19d sequentially via the ports 17a and 17c, the reception filter 15A, and the port 19a is in phase with the signal that is transmitted from the antenna terminal 5 to the port 19d sequentially via the ports 17a and 17d, the reception filter 15B, and the port 19b because both of the signals are subjected to the shift in phase by 90° once. Accordingly, the two signals are combined to be output from the port 19d to the reception terminal 9.

In contrast, the signal that is transmitted from the antenna terminal 5 to the port 19c sequentially via the ports 17a and 17c, the reception filter 15A, and the port 19a is not subjected to the shift in phase by 90°. The signal that is transmitted from the antenna terminal 5 to the port 19c sequentially via the ports 17a and 17d, the reception filter 15B, and the port 19b is subjected to the shift in phase by 90° twice. Accordingly, since the two signals are in opposite phase and are cancelled out, the signal is not output from the port 19c.

Although the signal that is input into the port 19a or 19b is described to be distributed to the port 19c for convenience of description, the output of no signal from the port 19c substantially means that no signal is distributed to the port 19c. In other words, the strength of the signal to be output to the reception terminal 9 is equal to the strength of the signal input into the antenna terminal 5 if the insertion loss is ignored.

### (1.2.3. Example of Reduction of Nonlinear Distortion)

The nonlinear distortion (the distortion signal), such as the intermodulation distortion, may occur in the transmission filter 13 and/or the reception filter 15 due to the nonlinearity of the transmission filter 13 and/or the reception filter 15. An example of an aspect will be described, in which the nonlinear distortion is reduced by using the hybrid. The reduction of the nonlinear distortion described here is caused by the hybrid itself and is not caused by the trap 24.

It is assumed that two signals have been input into the transmission terminal 7 and the nonlinear distortion has occurred in the transmission filter 13. It is assumed that this nonlinear distortion has a frequency within the reception band of the reception filter 15 and is capable of being transmitted through the reception filter 15.

The nonlinear distortion input from the transmission filter 13 to the port 17b is distributed to the ports 17c and 17d. The phase of the nonlinear distortion distributed to the port 17c is shifted from the phase of the nonlinear distortion distributed to the port 17d by 90°.

The nonlinear distortion that is distributed to the port 17c and that is output from the port 17c is input into the port 19a of the second hybrid 19 via the reception filter 15A. The nonlinear distortion that is distributed to the port 17d and that is output from the port 17d is input into the port 19b of the second hybrid 19 via the reception filter 15B.

The nonlinear distortion input into the port 19a is distributed to the ports 19c and 19d. At this time, the phase of the nonlinear distortion distributed to the port 19d is shifted from the phase of the nonlinear distortion distributed to the port 19c by 90°. Similarly, the nonlinear distortion input into the port 19b is distributed to the ports 19c and 19d. At this time the phase of the nonlinear distortion distributed to the port 19c is shifted from the phase of the nonlinear distortion distributed to the port 19d by 90°.

The nonlinear distortion that is transmitted from the transmission filter 13 to the port 19d sequentially via the ports 17b and 17c, the reception filter 15A, and the port 19a is subjected to the shift in phase by 90° twice. The nonlinear distortion that is transmitted from the transmission filter 13 to the port 19d sequentially via the ports 17b and 17d, the reception filter 15B, and the port 19b is not subjected to the shift in phase by 90°. Accordingly, since the two nonlinear distortions are in opposite phase and are cancelled out, the nonlinear distortion is not output from the port 19d. In other words, the nonlinear distortion is not input into the reception terminal 9.

The nonlinear distortion that is transmitted from the transmission filter 13 to the port 19c sequentially via the ports 17b and 17c, the reception filter 15A, and the port 19a is in phase with the nonlinear distortion that is transmitted from the transmission filter 13 to the port 19c sequentially via the ports 17b and 17d, the reception filter 15B, and the port 19b because both of the nonlinear distortions are subjected to the shift in phase by 90° once. Accordingly, the two signals are combined to be input into the termination resistor 23 from the port 19c. The nonlinear distortion is then let out to the reference potential portion 11 via the termination resistor 23.

Next, it is assumed that, when the transmission signal that is input into the transmission terminal 7 from the outside and that is transmitted through the transmission filter 13 and the first hybrid 17 is reflected by the reception filter 15, the nonlinear distortion has occurred in the reception filter 15. The phase relationship of the nonlinear distortions occurring in the reception filters 15A and 15B is the same as or similar to the phase relationship of the nonlinear distortions described above which has occurred in the transmission filter 13 and which has been propagated to the reception filters 15A and 15B. Accordingly, the nonlinear distortion is absorbed in the termination resistor 23 according to the same principle as the one described above or a principle similar to the one described above (is not input into the reception terminal 9).

### (1.3. Trap)

The trap 24 lets the signal having a frequency within the reception band out to the reference potential portion 11, as described above. In other words, the provision of the trap 24 causes the signal having a frequency within the reception band to relatively easily flow into the reference potential portion 11, compared with the signal having a frequency outside the reception band (for example, within the transmission band). Various configurations are available to realize such an action. The following configuration is adopted in the first embodiment.

### (1.3.1. Configuration of Trap)

FIG. 2 is a schematic diagram illustrating part (from the transmission terminal 7 to the first hybrid 17) of the composite filter 1A in the first embodiment. The trap 24 in the first embodiment may be referred to as a trap 24A.

The ladder filter is exemplified as the transmission filter 13 in FIG. 2. Specifically, the transmission filter 13 includes multiple (may be one) series resonators 29S (series arms from another viewpoint) and multiple (may be one) parallel resonators 29P (parallel arms from another viewpoint), which are connected in a ladder shape. The multiple series resonators 29S are connected in series from the input side (the transmission terminal 7 side) to the output side (the first hybrid 17 side). The multiple parallel resonators 29P connect different positions on the signal path from the input side to the output side to the reference potential portion 11.

The composite filter 1A includes the trap resonator 29T as the trap 24A. The trap resonator 29T is positioned between the first hybrid 17 side (the output side) of the transmission filter 13 and the reference potential portion 11 (is connected in series to the transmission filter 13 and the reference potential portion 11). The impedance of the trap resonator 29T (the absolute value of the impedance) has a local minimum value at the resonant frequency. The resonant frequency of the trap resonator 29T is positioned within the reception band. Accordingly, in the nonlinear distortion that has occurred in the transmission filter 13, the signals having frequencies (the resonant frequency of the trap resonator 29T and frequencies near the resonant frequency) within the reception band flow into the reference potential portion 11 via the trap resonator 29T.

The trap resonator 29T is similar to the parallel resonator 29P positioned at the output side with respect to all the series resonators 29S (this parallel resonator 29P is not provided in the transmission filter 13 in FIG. 2) from the viewpoint of its connection aspect. However, the parallel resonator 29P in the transmission filter 13 has the resonant frequency in the transmission band while the trap resonator 29T has the resonant frequency in the reception band. In other words, the parallel resonator 29P and the trap resonator 29T have different characteristics.

The trap 24 may include two or more trap resonators 29T that are connected in parallel to each other although not particularly illustrated. In this case, the resonant frequencies (and/or anti-resonant frequencies) of the two or more trap resonators 29T may be equal to each other or may be different from each other. The trap resonator 29T composed of multiple resonators (multiple split resonators 29Tb) that are connected in series may be described below. The description of the resonant frequencies and the anti-resonant frequencies of the multiple resonators that are connected in series may be incorporated into the resonant frequencies and the anti-resonant frequencies of the multiple resonators that are connected in parallel unless inconsistency or the like is found.

The trap resonator 29T may have any configuration. For example, the trap resonator 29T may be a resonator using resonance of the piezoelectric body, may be a resonator using resonance of the dielectric body, may be an LC resonator circuit in which an inductor is combined with a capacitor, or may be a resonator in which two or more of the above ones are combined. For example, the resonator using the piezoelectric body may use the acoustic waves or may not use the acoustic waves (for example, the resonator using the piezoelectric vibrator). The acoustic waves may be, for example, the SAWs, the BAWs, the boundary acoustic waves, or the plate waves. An aspect may be exemplified in the description of the embodiment with no description, in which the trap resonator 29T is composed of the acoustic wave resonator.

### (1.3.2. Example of Configuration of Resonator in Trap)

FIG. 3 is a schematic diagram illustrating an example of the configuration of the trap resonator 29T.

The trap resonator 29T in the example in FIG. 3 may be referred to as a trap resonator 29Ta. The trap resonator 29Ta includes the multiple (four in the example in FIG. 3) split resonators 29Tb that are connected in series between the output side of the transmission filter 13 and the reference potential portion 11. Accordingly, the probability that high pressure locally occurs in the trap resonator 29Ta is capable of being reduced with voltage dividing. Each split resonator 29Tb may be considered as an example of the trap resonator 29T, unlike the description here.

Each split resonator 29Tb is composed of the acoustic wave resonator (will be described in detail in Section 4). The split resonator 29Tb may have any specific configuration in this case. For example, in the example in FIG. 3, the split resonators 29Tb that are adjacent to each other share part of the IDT electrodes 33 (bus bars described below) and share part of reflectors 35 (bas bars described below). However, such sharing may not be performed.

The resonator composed of the multiple split resonators that are connected in series may also be applied to a resonator other than the trap resonator 29T (for example, the resonator in the transmission filter 13 and/or the resonator in the reception filter 15). The multiple series resonators 29S are common to the multiple split resonators 29Tb in a point in which the resonators are connected in series. Whether the split resonators are applied to the series resonator 29S is capable of being determined based on the positions where the one or more parallel resonators 29P are connected to the signal path including the series resonator 29S. In other words, when the multiple resonators are included in one area (one series arm) divided by the one or more parallel resonators 29P on the signal path, the multiple resonators are the split resonators.

The resonant frequency of each split resonator 29Tb is positioned within the reception band. The resonant frequency of the trap resonator 29Ta is also positioned within the reception band. When the resonator used in the ladder filter or the like is composed of the multiple split resonators, the multiple split resonators normally have substantially the same characteristics (for example, resonant frequency). In the trap resonator 29Ta, the split resonators 29Tb may have substantially the same characteristic or the characteristics of the split resonators 29Tb may be different from each other to an extent in which the split resonators 29Tb are not described to have substantially the same characteristic.

The resonant frequencies of (part or all of) the multiple split resonators 29Tb may be equal to each other or may be different from each other. In the latter aspect, in the characteristics of the entire trap resonator 29Ta, the local minimum value (a resonance point) of the absolute value of the impedance may appear in multiple frequencies within the reception band or may appear in one frequency within the reception band. In other words, the trap resonator 29Ta may have the multiple resonant frequencies or may have one resonant frequency. Similarly, the anti-resonant frequencies described below of (part or all of) the multiple split resonators 29Tb may be equal to each other or may be different from each other.

The trap resonator 29Ta may include any number of the split resonators 29Tb (the trap resonator 29Ta may have any split number). For example, the split number may be two to six (four in the example in FIG. 3). For example, an aspect is supposed, in which the transmission filter 13 is the ladder filter. At this time, the split number of the trap resonator 29Ta may be smaller than, equal to, or greater than the split number of the series resonator 29S closest to the output side of the transmission filter 13 and/or the split number of the parallel resonator 29P closest to the output side of the transmission filter 13. The aspect in which the split number of the trap resonator 29Ta is greater than the split number of the series resonator 29S and/or the parallel resonator 29P includes an aspect in which the series resonator 29S and/or the parallel resonator 29P is not split.

### (1.3.3. Example of Characteristics of Resonator in Trap)

FIG. 4 is a graph indicating an example of the characteristics of the trap resonator 29T. Although the description here may be incorporated in the trap resonator 29Ta, the description here may be incorporated in each split resonator 29Tb unless inconsistency or the like is found.

Referring to FIG. 4, the horizontal axis represents frequency f (Hz) and the frequency is increased rightward. The vertical axis on the left side represents transmission characteristic (dB) (represented as “S21 (dB)” in FIG. 4) and the value is increased upward (the signal is easily transmitted). The vertical axis on the right side represents the absolute value |Z| (Ω) of impedance and the value is increased upward.

A line LBT indicates the transmission characteristic of the transmission filter 13. A line LBR indicates the transmission characteristic of the reception filter 15. The value of the transmission characteristic is increased in a transmission band BT in the transmission filter 13. The value of the transmission characteristic is increased in a reception band BR in the reception filter 15. In the example in FIG. 4, the reception band is positioned at the low frequency side with respect to the transmission band. However, the relationship between both the reception band and the transmission band may be opposite to the above one. The passband (the reception band and the transmission band) may be appropriately defined. For example, the passband may be a frequency band the transmission characteristic of which is not lower than −3 dB and not higher than 0 dB.

A line X1 represents |Z| of the trap resonator 29T. In an impedance characteristic of the trap resonator 29T composed of the acoustic wave resonator, a resonance point X1r at which |Z| has the local minimum value and an anti-resonance point X1a at which |Z| has a local maximum value appear. The frequency at which the resonance point X1r appears is a resonant frequency fxr. The frequency at which the anti-resonance point X1a appears is an anti-resonant frequency fxa. In the example in FIG. 4, the anti-resonant frequency fxa is positioned at the high frequency side with respect to the resonant frequency fxr (at the same side as the side at which the transmission band is positioned with respect to the reception band from another viewpoint). However, the relationship between the resonant frequency fxr and the anti-resonant frequency fxa (whether the anti-resonant frequency fxa is positioned at the high frequency side with respect to the resonant frequency fxr and/or is positioned at the same side as the side at which the transmission band is positioned with respect to the reception band) may be opposite to the above one.

The resonant frequency fxr may be positioned at any frequency within the reception band BR. For example, the resonant frequency fxr may be the frequency of the nonlinear distortion (for example, PIM3) included in the reception band, may be a frequency near the frequency of the nonlinear distortion included in the reception band, or may be a frequency apart from the frequency of the nonlinear distortion included in the reception band. In an aspect in which multiple resonance points appear due to the multiple split resonators 29Tb, all the resonant frequencies fxr may be positioned at the frequency of the nonlinear distortion or near the frequency of the nonlinear distortion, only part of the resonant frequencies fxr may be positioned at the frequency of the nonlinear distortion or near the frequency of the nonlinear distortion, or all the resonant frequencies fxr may be apart from the frequency of the nonlinear distortion.

For example, when the reception band BR is divided into equal thirds or equal fifths, the resonant frequency fxr may be positioned in a central band (the example in FIG. 4) or may be positioned in another low-frequency side band or another high-frequency side band. In the aspect in which the multiple resonance points appear due to the multiple split resonators 29Tb, the multiple (all the) resonant frequencies fxr may be within the central band when the reception band BR is divided into equal thirds or equal fifths, may be within another low-frequency side band or another high-frequency side band, or may be dispersed in two or more bands or all the bands. Part of the resonant frequencies fxr may be positioned outside the reception band BR.

The anti-resonant frequency fxa of the trap resonator 29T may have any value. For example, the anti-resonant frequency fxa may be positioned within the reception band BR or may be positioned outside the reception band BR (the example in FIG. 4). In the latter aspect, any frequency difference may be made between the anti-resonant frequency fxa and the reception band BR (an end at the anti-resonant frequency fxa side of the reception band BR). For example, the frequency difference may be half or less of a band width of the reception band BR, may be half or more of the band width of the reception band BR, or may be equal to or greater than the band width of the reception band BR. When multiple anti-resonance points appear due to the multiple split resonators 29Tb, the aspect in which the anti-resonant frequency fxa is, for example, positioned within the reception band BR or outside the reception band BR may be common to all the anti-resonant frequencies fxa or may be varied between part of the anti-resonant frequencies fxa and another part of the anti-resonant frequencies fxa.

For example, in an aspect in which the anti-resonant frequency fxa is positioned outside the reception band BR and the side at which the anti-resonant frequency fxa is positioned with respect to the resonant frequency fxr is the same side as the side at which the transmission band BT is positioned with respect to the reception band BR (at the high-frequency side in the example in FIG. 4), the anti-resonant frequency fxa may be positioned within the transmission band BT (the example in FIG. 4) or may be positioned outside the transmission band BT (at the reception band BR side or the opposite side). In the aspect in which the multiple anti-resonance points appear, all the anti-resonant frequencies fxa may be positioned within the transmission band BT, part of the anti-resonant frequencies fxa may be positioned within the transmission band BT, or all the anti-resonant frequencies fxa may be positioned outside the transmission band BT.

In the aspect in which the anti-resonant frequency fxa is positioned within the transmission band BT, when the transmission band BT is divided into equal thirds or equal fifths, the anti-resonant frequency fxa may be positioned in a central band (the example in FIG. 4) or may be positioned in another low-frequency side band or another high-frequency side band. In the aspect in which the multiple anti-resonance points appear due to the multiple split resonators 29Tb, the multiple (for example, all the) anti-resonant frequencies fxa may be within the central band when the transmission band BT is divided into equal thirds or equal fifths, may be within another low-frequency side band or another high-frequency side band, or may be dispersed in two or more bands or all the bands.

The impedance characteristics of the series resonator 29S and the parallel resonator 29P are also indicated in FIG. 4 to facilitate the understanding of the impedance characteristic of the trap resonator 29T. An aspect is exemplified here, in which each of the transmission filter 13 and the reception filter 15 is composed of the ladder filter.

A line LTS indicates the |Z| of the series resonator 29S in the transmission filter 13. A line LTP indicates the |Z| of the parallel resonator 29P in the transmission filter 13. Also in these resonators, resonance points TSr and TPr and anti-resonance points TSa and TPa appear, as in the trap resonator 29T. Each resonator is configured so the resonant frequency of the series resonator 29S (the frequency at the resonance point TSr) substantially coincide with the anti-resonant frequency of the parallel resonator 29P (the frequency at the anti-resonance point TPa). This composes the ladder filter (the transmission filter 13) having a band slightly narrower than the frequency band from the resonant frequency of the parallel resonator 29P (the frequency at the resonance point TPr) to the anti-resonant frequency of the series resonator 29S (the frequency at the anti-resonance point TSa) as the passband (the transmission band BT).

The same applies to the reception filter 15. Specifically, a line LRS indicates the |Z| of the series resonator 29S in the reception filter 15. A line LRP indicates the |Z| of the parallel resonator 29P in the reception filter 15. Also in these resonators, resonance points RSr and RPr and anti-resonance points RSa and RPa appear. Each resonator is configured so the resonant frequency of the series resonator 29S (the frequency at the resonance point RSr) substantially coincide with the anti-resonant frequency of the parallel resonator 29P (the frequency at the anti-resonance point RPa). This composes the ladder filter (the reception filter 15) having a band slightly narrower than the frequency band from the resonant frequency of the parallel resonator 29P (the frequency at the resonance point RPr) to the anti-resonant frequency of the series resonator 29S (the frequency at the anti-resonance point RSa) as the passband (the reception band BR).

As described above, the connection relationship of the trap resonator 29T is the same as or similar to the connection relationship of the parallel resonator 29P in the transmission filter 13. However, the resonant frequency fxr of the trap resonator 29T is positioned within the reception band BR while the resonant frequency of the parallel resonator 29P in the transmission filter 13 (the frequency at the resonance point TPr) is positioned within the transmission band BT (in a central portion of the transmission band BT).

In the series resonator 29S or the parallel resonator 29P, the frequency difference between the resonant frequency fxr and the anti-resonant frequency fxa (referred to as Δf in this paragraph) is roughly slightly greater than half of the band width of the passband. Such restriction does not apply to the trap resonator 29T. In the example in FIG. 4, Δf is greater than Δf of the series resonator 29S or the parallel resonator 29P. Although Δf may have any specific magnitude, for example, Δf of the trap resonator 29T may be more than double of Δf of the series resonator 29S or the parallel resonator 29P. Unlike the example in FIG. 4, Δf of the trap resonator 29T may be equal to or lower than Δf of the series resonator 29S or the parallel resonator 29P.

### (1.4. Characteristics of Comparative Example and Example)

Characteristics concerning PIM3 in the composite filters in a comparative example and an example of the first embodiment will be described.

A situation was considered, in which two signals having a frequency (f1 or f2) within the transmission band are input into the transmission filter 13 to cause PIM3 having a frequency of 2f1−f2. Various values were supposed as the values of f1 and f2 to check the level of PIM3. Specifically, f1, f2, and 2f1−f2 were set as follows: f1=1,805+X (MHz), f2=1,852.5+X (MHz), and 2f1−f2=1,757.5+X (MHz). Various values greater than or equal to zero (MHz) were set as X. In the comparative example, an inductor was provided, instead of the trap resonator 29T, in the example (the composite filter 1A).

FIG. 5 is a graph indicating PIM3 of the composite filter 1A in the comparative example and the example. Referring to FIG. 5, the horizontal axis represents frequency 2f1−f2 (MHz) and the vertical axis represents the level (dBc) of PIM3 flowing into the reception terminal 9.

A line L1 indicates the value of PIM3 calculated by experiment in the comparative example. A line L2 indicates the value of PIM3 calculated through simulation in the comparative example. A line L3 indicates the value of PIM3 calculated through simulation in the example.

As indicated in FIG. 5, the value of PIM3 is decreased in the example, compared with those in the comparative example. As described above in 1.2.3, the composite filter 1A is configured so as to be capable of reducing the nonlinear distortion with the first hybrid 17 and the second hybrid 19. It was confirmed that the nonlinear distortion is capable of being further reduced with the trap resonator 29T also in such a configuration.

### 2. Second Embodiment

The composite filter 1 in the second embodiment will be described. The composite filter 1 in the second embodiment may be referred to as a composite filter 1B (a reference numeral and letter is illustrated in FIG. 6). The composite filter 1B differs from the composite filter 1A in the first embodiment in the configuration of the trap 24. Specifically, the following configuration is adopted.

### (2.1. Trap)

FIG. 6 is a schematic diagram illustrating part of the composite filter 1B in the second embodiment and corresponds to FIG. 2 in the first embodiment. The trap 24 in the second embodiment may be referred to as a trap 24B.

The trap 24B includes a trap filter 51 positioned between the output side (the first hybrid 17 side) of the transmission filter 13 and the reference potential portion 11. The trap filter 51 transmits a signal having a frequency within the reception band. Accordingly, a signal having a frequency within the reception band is capable of being let out to the reference potential portion 11.

The trap filter 51 may be of an appropriate kind, such as a band pass filter, a low pass filter, or a high pass filter. The band pass filter may be assumed in the description of the embodiment with no description. For example, at least part of the passband of the band pass filter is overlapped with at least part of the reception band and the entire passband of the band pass filter is not overlapped with the transmission band. Since the passband of the transmission filter 13 is not overlapped with the passband of the trap filter 51, a combination of the transmission filter 13 and the trap filter 51 may be considered as a branching filter 55 (a duplexer or a diplexer).

The trap 24B may include appropriate components, in addition to the trap filter 51. For example, the trap 24B may include a termination resistor 53 between the trap filter 51 and the reference potential portion 11. The trap 24B may include a matching circuit (may be considered as part of the trap filter 51) (not illustrated) at an appropriate position although not particularly illustrated.

The trap filter 51 may have any configuration. The description of the configurations of the transmission filter 13 and the reception filter 15 may be incorporated in the trap filter 51. Roughly, the trap filter 51 may include, for example, the piezoelectric filter, the dielectric filter, and/or the LC filter. The piezoelectric filter may include the acoustic wave filter. The acoustic wave filter may be, for example, the ladder filter and/or the multi-mode filter. Any kind of the acoustic waves may be used. In one composite filter 1B that has been actually produced, the kind of the configuration concerning the trap filter 51 may be the same as those of other filters (13 and 15) or may be different from those of the other filters. The ladder filter is exemplified as the trap filter 51 in FIG. 6. The above description of the ladder filter may be incorporated in the trap filter 51 unless inconsistency or the like is found.

The passband of the trap filter 51 (the band pass filter) may be arbitrarily set, for example, as long as at least part of the passband is overlapped with at least part of the reception band and the passband is not overlapped with the transmission band. Specifically, for example, the passband of the trap filter 51 may coincide with the reception band (the entire passband of the trap filter 51 may be overlapped with the entire reception band), may be part of the reception band, or may be wider than the reception band and may include the entire reception band. Alternatively, part of the low frequency side or the high frequency side of the passband may be overlapped with part of the high frequency side of the reception band.

For example, in an aspect in which the overlapping range of the trap filter 51 with the reception band is part of the reception band, the width of the overlapping range may be less than half of the width of the reception band or may be more than half or more than one-third of the width of the reception band. When the reception band is divided into equal thirds or equal fifths, the overlapping range may include a central band or may include one or more bands at the low frequency side or one or more bands at the high frequency side while including the central band or not including the central band.

When the passband of the trap filter 51 substantially coincides with the reception band, the configuration of the trap filter 51 may be the same as or may be different from the configuration of the reception filter 15. Although the trap filter 51 and the transmission filter 13 may be considered as the branching filter 55, as described above, the configuration that has been actually produced as the branching filter 55 (for example, a chip) may be used for the composite filter 1B.

The trap filter 51 composed of the low pass filter is used in, for example, the aspect in which the reception band is lower than the transmission band, as in the example in FIG. 4. A cutoff frequency is, for example, apart from the end at the low frequency side of the reception band toward the high frequency side. Accordingly, the low pass filter transmits the signal having a frequency included in at least part of the reception band. The cutoff frequency is, for example, at the low frequency side with respect to the transmission band. Accordingly, the probability that the signal having a frequency within the transmission band is transmitted through the low pass filter is reduced. The cutoff frequency may have any specific value. For example, the cutoff frequency may be positioned at the low frequency side with respect to the center frequency of the reception band, may be positioned at the high frequency side with respect to the center frequency of the reception band, may be positioned within the reception band, or may be positioned at the high frequency side with respect to the reception band.

The trap filter 51 composed of the high pass filter is used in, for example, an aspect in which the reception band is higher than the transmission band, in contrast with the example in FIG. 4. The cutoff frequency is, for example, apart from the end at the high frequency side of the reception band toward the low frequency side. Accordingly, the high pass filter transmits the signal having a frequency included in at least part of the reception band. The cutoff frequency is, for example, at the high frequency side with respect to the transmission band. Accordingly, the probability that the signal having a frequency within the transmission band is transmitted through the high pass filter is reduced. The cutoff frequency may have any specific value. For example, the cutoff frequency may be positioned at the high frequency side with respect to the center frequency of the reception band, may be positioned at the low frequency side with respect to the center frequency of the reception band, may be positioned within the reception band, or may be positioned at the low frequency side with respect to the reception band.

When the trap filter 51 is the ladder filter, the series resonator 29S in the trap filter 51 connects the output side (the first hybrid 17 side) of the transmission filter 13 to the reference potential portion 11 (more strictly, the termination resistor 53), as apparent from the above description, and has the resonant frequency positioned within the reception band. Accordingly, the series resonator 29S in the trap filter 51 may be considered as one kind of the trap resonator 29T.

When the trap filter 51 is a longitudinally coupled multi-mode filter, the multiple resonators (resulting from exclusion of the reflectors 35 from a resonator 29 in FIG. 10, as described below) in the trap filter 51 include at least one resonator with which the output side of the transmission filter 13 is connected to the reference potential portion 11 (more strictly, the termination resistor 53) although not particularly illustrated. This resonator has the resonant frequency in the reception band. Accordingly, this resonator may also be considered as one kind of the trap resonator 29T.

Also in other aspects, when the trap filter 51 includes the resonator with which the output side of the transmission filter 13 is connected to the reference potential portion 11 and the resonant frequency of which is positioned within the passband, this resonator may be considered as one kind of the trap resonator 29T.

The structure of the composite filter 1B may be realized in various aspects, like the structure of the composite filter 1A. The description of the structures of the transmission filter 13 and the reception filter 15 may be incorporated in the structure of the trap filter 51. Roughly, for example, the trap filter 51 may be a chip mounted on the circuit board (for example, the multilayer substrate) or may be incorporated in the circuit board. Part of the trap filter 51 or the entire trap filter 51 may be assembled into one chip with part of other filters (13 and/or 15) or the entire other filters.

The description of the termination resistor 23 may be incorporated in the termination resistor 53 except the specific connection target. Roughly, the resistance value of the termination resistor 53 may be appropriately set in accordance with the impedance at the trap filter 51 side with respect to the termination resistor 53 and the termination resistor 53 generally has a resistance value of 50Ω. The termination resistor 53 may be provided on the circuit board on which the filter (13, 15 and/or 51) is mounted or may be provided in the piezoelectric substrate 31 (described below) composing the filter. The termination resistor 53 may a mounted resistor, an embedded resistor, or a built-in resistor.

### (2.2. Characteristics of Comparative Example and Example)

Characteristics of a comparative example and an example (the composite filter 1B) of the second embodiment will be described. The characteristics described below are calculated through simulation.

The situation was considered here, in which two signals having a frequency within the transmission band are input into the transmission filter 13 to cause PIM3 of 2f1−f2, as in the first embodiment. In addition, f1, f2, and 2f1−f2 were set as follows: f1=1,805+X (MHz), f2=1,852.5+X (MHz), and 2f1−f2=1,757.5+X (MHz), as in the first embodiment. However, FIG. 7A and FIG. 7B indicate characteristics when X was fixed to a predetermined value. FIG. 8A and FIG. 8B indicate characteristics when X was varied. In the comparative example, the trap 24B was removed from the composite filter 1B.

FIG. 7A is a graph indicating the transmission characteristics of the comparative example and the example. The horizontal axis represents frequency f (GHz). The vertical axis represents transmission characteristic (dB). Referring to FIG. 7A, approximately 1.7 GHz to 1.8 GHz corresponds to the reception band and approximately 1.8 GHz to 1.9 GHz corresponds to the transmission band.

Lines L5Tt and L5Tr indicate the characteristics of the comparative example. Lines L6Tt and L6Tr indicate the characteristics of the example. The lines L5Tt and L6Tt indicate the transmission characteristics concerning the transmission path 2T. Since both of the lines L5Tt and L6Tt are approximately overlapped with each other in the transmission band, the reference numerals and letters are added in the reception band. The lines L5Tr and L6Tr indicate the transmission characteristics concerning the reception path 2R. Since both of the lines L5Tr and L6Tr are approximately overlapped with each other in the reception band, the reference numerals and letters are added in the transmission band.

As indicated in this graph, the transmission characteristic of the transmission path 2T in the reception band (including the frequency of PIM3) is reduced in the example, compared with the comparative example. In other words, the signal in the reception band has difficulty in being transmitted on the transmission path 2T of the example. Accordingly, the composite filter 1B has the improved characteristics as the branching filter.

FIG. 7B is a graph indicating isolation characteristics of the comparative example and the example. The horizontal axis represents frequency f (GHz). The vertical axis represents isolation (dB). A line L5I indicates the characteristic of the comparative example. A line L6I indicates the characteristic of the example.

As indicated in this graph, the isolation is improved at the frequency of PIM3 or frequencies near the frequency of PIM3 (approximately 1.75 GHz to 1.76 GHZ) in the example, compared with the comparative example. In other words, the composite filter 1B has the improved characteristics as the branching filter.

FIG. 8A is a graph indicating characteristics concerning PIM3 of the comparative example and the example. The horizontal axis represents the frequency 2f1−f2 (MHz) of PIM3 (denoted as “1,757.5+X (MHz)”). The vertical axis represents the level (dBm) of PIM3 flowing into the reception terminal 9. A line L5P indicates the characteristic of the comparative example. A line L6P indicates the characteristic of the example.

As indicated in this graph, PIM3 flowing into the reception terminal 9 is reduced in the example, compared with the comparative example. Accordingly, although the composite filter 1B is configured so as to be capable of reducing the nonlinear distortion, as in the first embodiment, it was confirmed that the nonlinear distortion is further reduced with the trap filter 51.

FIG. 8B is a graph indicating characteristics concerning PIM3 of the comparative example and the example. The horizontal axis in FIG. 8B is similar to the one in FIG. 8A. The vertical axis represents the level of PIM3 (denoted as “PIM3-T (dBm)”) output from the trap filter 51 to the reference potential portion 11 side. A line in the graph indicates the characteristic of the example.

Comparison between FIG. 8A and FIG. 8B indicates that the level of PIM3 flowing into the reception terminal 9 is correlated with the level of PIM3 flowing into the trap filter 51. In other words, it was confirmed that the reduction of PIM3 flowing into the reception terminal 9 is owing to the trap filter 51.

### 3. Third Embodiment

FIG. 9 is a circuit diagram illustrating the configuration of a composite filter 301 in the third embodiment.

The composite filter 301 simply has a configuration in which the second hybrid 19 is removed, reception terminals 9A and 9B corresponding to the reception filters 15A and 15B, respectively, are provided, and a 90° phase shifter 20 (hereinafter simply referred to as a “phase shifter 20”) is provided between the reception filter 15B and the reception terminal 9B in the composite filter 1 in the first or second embodiment. The configuration of the trap 24 may be the same as or similar to that in the first or second embodiment.

An action concerning the transmission of the transmission signal input from the outside of the composite filter 301 into the transmission terminal 7 is the same as or similar to the one in the first embodiment. An action concerning the transmission of the reception signal input from the outside of the composite filter 301 into the antenna terminal 5 is the same as or similar to the one in the first embodiment before the reception signal is transmitted through the reception filters 15A and 15B. Then, the phase of the reception signal transmitted through the reception filter 15B is shifted by 90° by the phase shifter 20. Accordingly, the phase of the reception signal transmitted through the reception filter 15B is shifted from the phase of the reception signal transmitted through the reception filter 15A by 180°, which results from addition to the shift in phase by the first hybrid 17. Consequently, the two reception signals are output from the two reception terminals 9 (9A and 9B) as a balanced signal indicating the signal strength by a difference in potential between the two reception signals.

In the composite filter 301, the signal (for example, the nonlinear distortion) distributed from the transmission filter 13 to the reception filters 15A and 15B by the first hybrid 17 is finally made the in-phase signals by the phase shifter 20 to be output to the reception terminals 9A and 9B. Accordingly, the signal from the transmission filter 13 has no influence on the difference in potential of the balanced signal described in the previous paragraph in principle. In other words, the nonlinear distortion output from the reception terminals 9A and 9B to the outside of the composite filter 301 is substantially reduced.

### 4. Example of Acoustic Wave Resonator

As described above, the trap resonator 29T (29Ta), the split resonator 29Tb, and the series resonator 29S and/or the parallel resonator 29P composing the filter (13, 15, and/or 51) may be the acoustic wave resonators. An example of the acoustic wave filter will be described. The above various resonators and the acoustic wave resonator are collectively referred to as the resonator 29 here.

FIG. 10 is a plan view schematically illustrating the configuration of the resonator 29.

Although any direction may be set as the upper direction or the lower direction in the resonator 29, an orthogonal coordinate system composed of a D1 axis, a D2 axis, and a D3 axis is illustrated in FIG. 10 for convenience and the terms of the top face, the bottom face, and so on may be used with the +D3 side (the front side of sheet of paper) being defined as the upper direction in the following description. The D1 axis is defined so as to be parallel to the propagation direction of the acoustic waves propagated along the top face of a piezoelectric body described below, the D2 axis is defined so as to be parallel to the top face of the piezoelectric body and to be orthogonal to the D1 axis, and the D3 axis is defined so as to be orthogonal to the top face of the piezoelectric body.

The resonator 29 is composed of a so-called one-port acoustic wave resonator. For example, the resonator 29 outputs a signal input through one of two terminals 28, which are schematically illustrated on both sides in the left-right direction in FIG. 10, from the other of the two terminals 28. At this time, the resonator 29 performs conversion from an electric signal into the acoustic waves and conversion from the acoustic waves into the electric signal. The terminal 28 may correspond to, for example, any of the antenna terminal 5, the transmission terminal 7, the reception terminal 9, and the reference potential portion 11.

The resonator 29 includes, for example, the piezoelectric substrate 31 (part of at least the top face 31a side of the piezoelectric substrate 31), the IDT electrodes 33 (excitation electrodes) positioned on the top face 31a, and the pair of reflectors 35 positioned on both sides of the IDT electrodes 33. Multiple resonators 29 may be configured on one piezoelectric substrate 31. In other words, the multiple resonators 29 may share the piezoelectric substrate 31.

The piezoelectric substrate 31 has the piezoelectricity in at least an area where the resonators 29 are provided on the top face 31a. The piezoelectric body 31b composing the area where at least the resonators 29 are provided on the piezoelectric substrate 31 is composed of, for example, single crystal having the piezoelectricity. For example, lithium tantalate (LiTaO₃), lithium niobate (LiNbO₃), and quartz crystal (SiO₂) are exemplified as the material composing such single crystal. Cut-angles, the planar shape, and various sizes may be appropriately set. For example, the entire piezoelectric substrate 31 may be composed a piezoelectric body (may be a piezoelectric substrate). The piezoelectric substrate 31 may be a substrate in which the piezoelectric substrate is bonded to a supporting substrate or a substrate in which multiple films are laminated on the supporting substrate and a piezoelectric layer is imposed on the multiple films, or a substrate including cavity provided between the piezoelectric layer and the supporting substrate.

The IDT electrodes 33 and the reflectors 35 are composed of layered conductors provided on the piezoelectric substrate 31. The IDT electrodes 33 is composed of so-called IDT electrodes and includes a pair of comb-shaped electrodes 37 (the comb-shaped electrode 37 at one side is hatched to improve the visibility for convenience). Each comb-shaped electrode 37 includes, for example, a bus bar 39, multiple electrode fingers 41 extending in parallel from the bus bar 39, and multiple dummy electrodes 43 projecting from the bus bar 39 between the multiple electrode fingers 41. The pair of comb-shaped electrodes 37 is arranged so that the multiple electrode fingers 41 are engaged (intersect) with each other.

The pair of reflectors 35 is positioned on both sides of the IDT electrodes 33 in the propagation direction of the acoustic waves. Each reflector 35 may be, for example, in an electrically floating state or the reference potential may be added to each reflector 35. Each reflector 35 is formed in, for example, a grid shape. In other words, the reflector 35 includes a pair of bus bars 45 opposed to each other and multiple strip electrodes 47 extending between the pair of bus bars 45.

Upon application of voltage to the pair of comb-shaped electrodes 37, the voltage is applied to the piezoelectric body 31b with the multiple electrode fingers 41 to vibrate the piezoelectric body 31b. In other words, the acoustic waves are excited. In the acoustic waves that have a pitch p of the multiple electrode fingers 41, which is approximately a half wavelength (λ/2), and that are propagated in an alignment direction of the multiple electrode fingers 41, among the acoustic waves of various wavelengths propagating in various directions, since the multiple waves excited by the multiple electrode fingers 41 are overlapped with each in phase, the amplitude is likely to be increased.

The acoustic waves propagated through the piezoelectric body 31b are converted into the electric signal by the multiple electrode fingers 41. At this time, as in the case in which the acoustic waves are excited, the strength of the electric signal resulting from conversion of the acoustic waves that have the pitch p of the multiple electrode fingers 41, which is approximately the half wavelength (λ/2), and that are propagated in the alignment direction of the multiple electrode fingers 41 is likely to be increased.

Due to the above action (and other actions the description of which is omitted here), the resonator 29 functions as a resonator having the frequency of the acoustic waves that have the pitch p, which is approximately the half wavelength (λ/2), as the resonant frequency. The anti-resonant frequency is determined by the resonant frequency, the capacitance of the IDT electrodes 33, and so on. The pair of reflectors 35 contributes to trapping of the acoustic waves.

A configuration excluding the pair of reflectors 35 from the resonator 29 (the one-port resonator) is also one kind of the resonator. Aligning the two or more IDT electrodes 33 (the resonator resulting from exclusion of the pair of reflectors) between the pair of reflectors 35 composes the longitudinally coupled multi-mode filter.

In an aspect in which the resonator using the IDT electrodes 33 uses the BAWs, the resonator may cause the BAWs propagating in the D1 direction due to the same action as the above one or an action similar to the above one or may cause thickness-shear vibration due an action different from the above one. In the latter case, the resonant frequency has relatively high dependence on the thickness of the piezoelectric layer and has relatively low dependence on the pitch p. Even in the one-port resonator, the pair of reflectors 35 may not be provided.

### 5. Example of Communication Apparatus Including Composite Filter

The composite filter may be used for, for example, a module for communication and/or a communication apparatus. An example of this will be described.

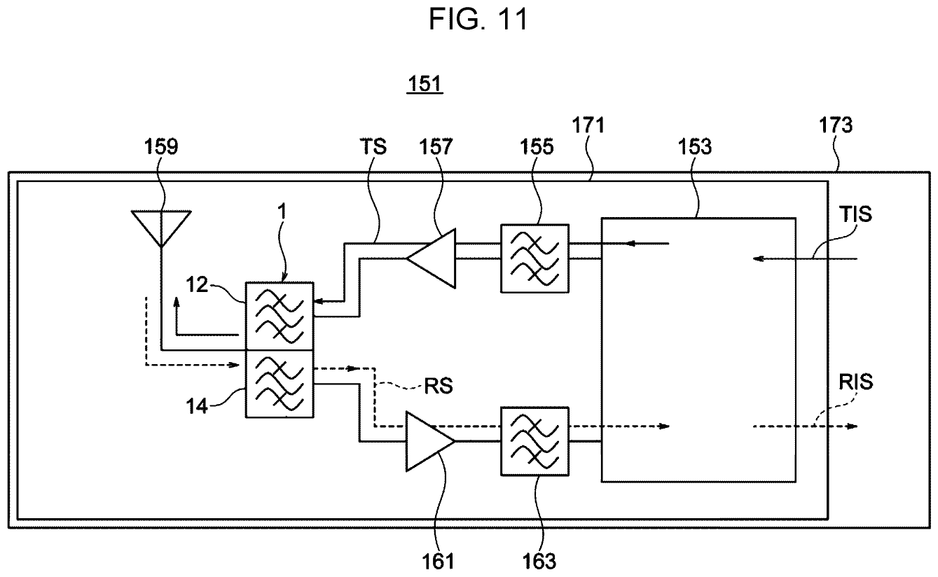

FIG. 11 is a block diagram illustrating the major portion of a communication apparatus 151 as an example of use of the composite filter 1. The communication apparatus 151 includes a module 171 and a housing 173 housing the module 171. The module 171 performs wireless communication using radio waves and includes the composite filter 1. Only the transmission filter system 12 and the reception filter system 14 in the composite filter 1 are illustrated in FIG. 11 and illustration of the hybrids and so on is omitted.

In the module 171, a transmission information signal TIS including information to be transmitted is subjected to modulation and rising of the frequency (conversion into a radio frequency signal having a carrier wave frequency) by an RF-IC (radio frequency integrated circuit) 153 to be a transmission signal TS. Unnecessary components other than a passband for transmission in the transmission signal TS are removed by a band pass filter 155. The transmission signal TS is amplified by an amplifier 157 to be input into the composite filter 1 (the transmission terminal 7). The composite filter 1 (the transmission filter system 12) removes the unnecessary components other than the passband for transmission from the input transmission signal TS and outputs the transmission signal TS from which the unnecessary components are removed to an antenna 159 through the antenna terminal 5. The antenna 159 converts the input electric signal (the transmission signal TS) into a radio signal (the radio waves) to transmit the radio signal.

In the module 171, the radio signal (the radio waves) received by the antenna 159 is converted into the electric signal (a reception signal RS) by the antenna 159 to be input into the composite filter 1 (the antenna terminal 5). The composite filter 1 (the reception filter system 14) removes unnecessary components other than a passband for reception from the input reception signal RS to output the reception signal RS from the reception terminal 9 to an amplifier 161. The output reception signal RS is amplified by the amplifier 161 and the unnecessary components other than the passband for reception are removed from the reception signal RS by a band pass filter 163. The reception signal RS is subjected to falling of the frequency and demodulation by the RF-IC 153 to be a reception information signal RIS.

The transmission information signal TIS and the reception information signal RIS may be low-frequency signals (baseband signals) including appropriate information and may be, for example, analog audio signals or digitalized audio signals. The passband of the radio signal may be appropriately set. The modulation method may be phase modulation, amplitude modulation, frequency modulation, or a combination of two or more of the above ones. Although a direct conversion method is illustrated as the circuit method, another appropriate circuit method may be adopted. For example, a double super-heterodyne method may be adopted. FIG. 11 schematically illustrates only the major portion. A low pass filter, an isolator, and/or the like may be added to an appropriate position or the positions of the amplifiers and so on may be varied.

The module 171 includes, for example, the components from the RF-IC 153 to the antenna 159 on the same circuit board. In other words, the composite filter 1 is modularized in combination with the other components. The composite filter 1 may be included in the communication apparatus 151 without being modularized. The components exemplified as the components of the module 171 may be positioned outside the module or may not be housed in the housing 173. For example, the antenna 159 may be exposed from the housing 173.

### 6. Summarization of Embodiments

As described above, the composite filter 1 in the embodiment includes the first hybrid 17, a first filter (for example, the transmission filter 13), second and third filters (for example, the reception filters 15A and 15B), and the resonator 29 in the trap 24 (for example, the trap resonator 29T in the first embodiment or the series resonator 29S in the trap filter 51 in the second embodiment). The first hybrid 17 is composed of a 90° hybrid coupler including a first port and a second port (the port 17a and the port 17b), and a third port and a fourth port (the ports 17c and 17d) to which a signal input into the port 17a or the port 17b is distributed. The first filter is connected to the port 17b and has a first passband (for example, the transmission band). The second filter is connected to the port 17c and has a second passband (for example, the reception band) that is not overlapped with the first passband. The third filter is connected to the port 17d and has the second passband. The resonator 29 is branched from a signal path from the first filter to the port 17b to be connected to the reference potential portion 11 and has the resonant frequency within the second passband.

Accordingly, for example, as described in Summary of embodiment, the probability that the nonlinear distortion that has occurred in the transmission filter 13 is transmitted through the reception filter 15 is capable of being reduced. Since the composite filter 1 itself using the first hybrid 17 is capable of reducing the nonlinear distortion, the effect of reducing the nonlinear distortion is further improved. Since it is assumed that the flow of the reception signal from the antenna terminal 5 to the transmission filter 13 is basically blocked with the first hybrid 17, the trap 24 has difficulty of being supposed from the branching filter that does not include the first hybrid 17.

The composite filter 1 may include the second hybrid 19. The second hybrid 19 may be composed of a 90° hybrid coupler including a fifth port and a sixth port (the ports 19a and 19b), and a seventh port and an eighth port (the ports 19c and 19d) to which a signal input into the fifth port or the sixth port is distributed. The port 19a may be electrically connected to a side opposite to a side at which the first hybrid 17 is connected with respect to the second filter (for example, the reception filter 15A). The port 19b may be electrically connected to a side opposite to a side at which the first hybrid 17 is connected with respect to the third filter (for example, the reception filter 15B).

In this case, for example, at least part of the nonlinear distortions is capable of being offset at the port 19d, as described above. The signal input into the port 19a or 19b is represented to be distributed to the ports 19c and 19d in the previous paragraph. However, as mentioned above and as apparent from the first and second embodiments, the above representation is made for convenience. In other words, an intended signal may not be input into the port 19a or 19b.

The resonator 29 (for example, the trap resonator 29T in the first embodiment or the series resonator 29S in the trap filter 51 in the second embodiment) in the trap 24 may include the multiple split resonators 29Tb that are connected in series to each other between the second port (the port 19b) side of the first filter (for example, the transmission filter 13) and the reference potential portion 11.

In this case, the probability that the voltage locally applied to the trap resonator 29Ta is made high is capable of being reduced, as described above. As a result, the voltage resistance of the composite filter 1 is improved. Since the trap resonator 29Ta is positioned at the first hybrid 17 side, compared with the transmission filter 13, the trap resonator 29Ta has the higher probability that high voltage is applied from the first hybrid 17 side, compared with the resonator 29 in the transmission filter 13. This effectively improves the voltage resistance. When the split resonator 29Tb is applied to any of the multiple series resonators 29S in the trap filter 51 in the second embodiment, the voltage dividing by the series resonators 29S and the voltage dividing by the split resonator 29Tb are performed to further improve the voltage resistance of the resonator 29. From another viewpoint, in the trap resonator 29T in the first embodiment, the multiple split resonators 29Tb are capable of improving the voltage resistance of the entire composite filter 1 by reducing the probability that the trap resonator 29T first causes dielectric breakdown in the composite filter 1 or increasing the voltage when the dielectric breakdown first occurs.

The resonator 29 (for example, the trap resonator 29T in the first embodiment) in the trap 24 may have the anti-resonant frequency within the first passband (for example, the transmission band).

In this case, for example, the probability that the signal to be output from the transmission filter 13 to the antenna terminal 5 flows into the reference potential portion 11 through the trap resonator 29T is reduced. In other words, the probability that the insertion loss is reduced due to the trap 24 is reduced. The anti-resonant frequency of the series resonator 29S (may be considered as one kind of the trap resonator 29T) in the trap filter 51 in the second embodiment is positioned slightly outside the reception band. This anti-resonant frequency is not positioned within, for example, the transmission band.

The composite filter 1A (the first embodiment) may include no filter (no trap filter 51 in the second embodiment) including the trap resonator 29T is provided between the second port (the port 17b) side of the first filter (for example, the transmission filter 13) and the reference potential portion 11.

In this case, for example, the configuration is simplified, compared with the second embodiment. Accordingly, for example, when the transmission filter 13 is the acoustic wave filter, the composite filter 1A in the embodiment is capable of being realized only by adding the electrodes (the IDT electrodes 33 and the pair of reflectors 35) in the chip (the piezoelectric substrate 31) in which the transmission filter 13 is provided. As a result, for example, the degree of freedom of structural design is improved. Although the trap resonator 29T in the first embodiment may also be considered as one kind of the filter, such consideration is not taken when the content of the previous paragraph is adopted.

The composite filter 1B (the second embodiment) may include the fourth filter (the trap filter 51). The fourth filter may include the resonator 29 (for example, the series resonator 29S) in the trap 24. The fourth filter transmits a signal having a frequency within the second passband (for example, the reception band) from the second port (the port 17b) side of the first filter (for example, the transmission filter 13) to the reference potential portion 11.

In this case, for example, not only the nonlinear distortion at the resonant frequency of the resonator 29 in the trap 24 and at frequencies near the resonant frequency of the resonator 29 in the trap 24 is capable of being trapped but also the nonlinear distortion in a relatively wide band is capable of being trapped, compared with the first embodiment. As a result, for example, the nonlinear distortion outside an estimated frequency is also capable of being trapped.

The fourth filter (the trap filter 51) may include a band pass filter having a third passband that includes at least part of the second passband (for example, the reception band) and that does not include the first passband (for example, the transmission band).

In this case, for example, the probability that the transmission signal to be output from the transmission filter 13 to the antenna terminal 5 is trapped is reduced. In addition, for example, the chip produced as the branching filter 55 is capable of being used as a combination of the transmission filter 13 and the trap filter 51.

The entire third passband (the passband of the trap filter 51) may be overlapped with the entire second passband (for example, the reception band).

In this case, for example, the nonlinear distortion is capable of being trapped over the reception band. This enables, for example, the probability that the signal in the transmission band is trapped to be reduced while reducing the nonlinear distortion input into the reception terminal 9 through the reception filter 15. In addition, the trap filter 51 can have the same configuration as that of the reception filter 15 to expect improvement of productivity.

The composite filter 1B may include the termination resistor 53 between the fourth filter (the trap filter 51) and the reference potential portion 11.

In this case, the probability that the signal (the nonlinear distortion) transmitted through the trap filter 51 is reflected from the output side (the termination resistor 53 side) of the trap filter 51 is reduced. When the ladder filter is exemplified as the trap filter 51, the signal transmitted through the parallel resonator 29P (the signal outside the passband) is supposed to be let out to the reference potential portion 11. In contrast, the signal transmitted through the series resonator 29S (the signal in the passband) is not supposed to flow into the reference potential portion 11. Accordingly, the provision of the termination resistor 53 facilitates use of the design of the filter in related art.

From a viewpoint different from the above ones, the composite filter 1 in the embodiment (for example, the composite filter 1B in the second embodiment) includes the first hybrid 17, a first filter (for example, the transmission filter 13), second and third filters (for example, the reception filters 15A and 15B), and a fourth filter (for example, the trap filter 51). The first hybrid 17 is composed of a 90° hybrid coupler including a first port and a second port (the port 17a and the port 17b), and a third port and a fourth port (the ports 17c and 17d) to which a signal input into the port 17a or the port 17b is distributed. The first filter is connected to the port 17b and has a first passband (for example, the transmission band). The second filter is connected to the port 17c and has a second passband (for example, the reception band) that is not overlapped with the first passband. The third filter is connected to the port 17d and has the second passband. The fourth filter is branched from a signal path from the first filter to the port 17b to be connected to the reference potential portion 11 and transmits a signal having a frequency within the second passband.

Accordingly, for example, as described in Summary of embodiment, the probability that the nonlinear distortion that has occurred in the transmission filter 13 is transmitted through the reception filter 15 is capable of being reduced. When the composite filter 1 (1B) in the embodiment is considered in the above manner, the resonator 29 may not be provided, which is branched from the signal path from the first filter (the transmission filter 13) to the second port (the port 17b) to be connected to the reference potential portion 11 and which has the resonant frequency within the second passband (the reception band). For example, the trap filter 51 may be the low pass filter or the high pass filter that does not include the resonator and that is composed of an inductor, a capacitor, and so on or may be the band pass filter configured by making the cutoff frequency of the high pass filter lower than the cutoff frequency of the low pass filter.

The communication apparatus 151 in the embodiment may include the composite filter 1, the antenna 159 connected to the first port (the port 17a), and an integrated circuit element (the RF-IC 153) that is electrically connected to an opposite side of the first hybrid 17 with respect to the first filter and each of the second filter and the third filter.

In this case, for example, the effect of reducing the nonlinear distortion in the composite filter 1 described above is capable of being used in the communication apparatus 151. In addition, communication characteristics are improved.

In the above embodiments, the transmission filter 13 is an example of the first filter. The reception filters 15A and 15B are examples of the second and third filters, respectively. Each of the trap resonator 29T or 29Ta, the split resonator 29Tb in the trap resonator 29Ta, and the series resonator 29S in the trap filter 51 is an example of the resonator with which the first filter is connected to the reference potential portion. The trap filter 51 is an example of the fourth filter. The ports 17a to 17d and 19a to 19d are examples of the first to eighth ports, respectively. The RF-IC 153 is an example of the integrated circuit element.

The technology according to the present disclosure is not limited to the above embodiments and may be realized in various aspects.

For example, the first filter may be the reception filter (the transmission terminal 7 may be the reception terminal), and the second and third filters may be two reception filters having the reception band (the second passband) different from the reception band (the first passband) of the first filter. Also in this case, for example, the probability that the nonlinear distortion that has occurred in the first filter is input into the reception terminal 9 through the second and third filters is reduced. As apparent from the above description, the composite filter may be the diplexer, instead of the duplexer.

In addition, for example, the first filter may be the reception filter (the transmission terminal 7 may be the reception terminal), and the second and third filters may be the transmission filters (the reception terminal 9 (or 9A and 9B) may be the transmission terminal). The trap 24 may have the resonant frequency and/or the passband within the transmission band. Also in this case, the probability that the nonlinear distortion that has occurred in any of the first to third filters appears at any terminal is reduced.

Furthermore, for example, the composite filter in the embodiment may be part of a multiplexer, such as a triplexer or a quadplexer.

### REFERENCE SIGNS

1, 1A, 1B, 301 composite filter
11 reference potential portion
13 transmission filter (first filter)
15, 15A, 15B reception filter (second filter, third filter)
17 first hybrid
17a port (first port)
17b port (second port)
17c port (third port)
17d port (fourth port)
29 resonator
29T, 29Ta trap resonator (resonator)
29S series resonator (resonator)
29Tb split resonator (resonator)
51 trap filter (fourth filter)

1. A composite filter comprising:
a first hybrid composed of a 90° hybrid coupler comprising a first port, a second port, and a third port and a fourth port to which a signal input into the first port or the second port is distributed;
a first filter that is connected to the second port and that has a first passband;
a second filter that is connected to the third port and that has a second passband that is not overlapped with the first passband;
a third filter that is connected to the fourth port and that has the second passband; and
a resonator that is branched from a signal path from the first filter to the second port to be connected to a reference potential portion and that has a resonant frequency within the second passband.

2. The composite filter according to claim 1, further comprising:
a second hybrid composed of a 90° hybrid coupler comprising a fifth port, a sixth port, and a seventh port and an eighth port to which a signal input into the fifth port or the sixth port is distributed,
wherein the fifth port is electrically connected to a side opposite to a side at which the first hybrid is connected with respect to the second filter, and
wherein the sixth port is electrically connected to a side opposite to a side at which the first hybrid is connected with respect to the third filter.

3. The composite filter according to claim 1,
wherein the resonator comprises a plurality of split resonators that is connected in series to each other between the second port side of the first filter and the reference potential portion.

4. The composite filter according to claim 1,
wherein the resonator has an anti-resonant frequency within the first passband.

5. The composite filter according to claim 1,
wherein no filter comprising the resonator is provided between the second port side of the first filter and the reference potential portion.

6. The composite filter according to claim 1, further comprising:
a fourth filter that comprises the resonator and that transmits a signal having a frequency within the second passband from the second port side of the first filter to the reference potential portion.

7. A composite filter comprising:
a first hybrid composed of a 90° hybrid coupler comprising a first port, a second port, and a third port and a fourth port to which a signal input into the first port or the second port is distributed;
a first filter that is connected to the second port and that has a first passband;
a second filter that is connected to the third port and that has a second passband that is not overlapped with the first passband;
a third filter that is connected to the fourth port and that has the second passband; and
a fourth filter that is branched from a signal path from the first filter to the second port to be connected to a reference potential portion and that transmits a signal having a frequency within the second passband to the reference potential portion.

8. The composite filter according to claim 6,
wherein the fourth filter comprises a band pass filter having a third passband that includes at least part of the second passband and that does not include the first passband.

9. The composite filter according to claim 8,
wherein the entire third passband is overlapped with the entire second passband.

10. The composite filter according to claim 6, further comprising:
a termination resistor between the fourth filter and the reference potential portion.

11. A communication apparatus comprising:
the composite filter according to claim 1;
an antenna connected to the first port; and
an integrated circuit element that is electrically connected to an opposite side of the first hybrid with respect to the first filter and each of the second filter and the third filter.
